(19) United States
(12) Patent Application Publication
(10) Pub. No.: US 2023/0412132 A1
(43) Pub. Date: Dec. 21, 2023

(54) Voltage Generation Circuitry with Reduced Settling Time

(71) Applicant: Apple Inc., Cupertino, CA (US)

(72) Inventors: Wenbo Liu, Cupertino, CA (US); Shang Hsien Meng, Austin, TX (US); Sanjeev K. Maheshwari, Fremont, CA (US)

(21) Appl. No.: 17/841,870

(22) Filed: Jun. 16, 2022

(51) Int. Cl. H03F 3/393; H03F 3/45; H03F 1/26

(52) U.S. Cl. CPC H03F 3/393; H03F 3/45179; H03F 1/26; H03F 2200/271; H03F 2200/171; H03F 2200/555; H03F 3/347

(57) ABSTRACT

Low noise voltage generation circuitry includes a voltage source, a low-pass filter with one or more filter stages, and an amplifier selectively coupled to the filter stages. Each filter stage includes a resistor and a pair of capacitors of equal capacitance. The amplifier has an input selectively coupled to an output port of the voltage generation circuitry and has an output selectively coupled to the pair of capacitors in each filter stage. During a sensing phase, the amplifier senses the voltage at the output port. During a first charging phase, the amplifier has a first polarity and charges one of the pair of capacitors in each filter stage. During a second charging phase, the amplifier has a second polarity and charges another one of the pair of capacitors in each filter stage. During a final phase, the pair of capacitors within each filter stage are shorted together to cancel out an amplifier offset while the output port instantaneously settles to the target voltage.

### FIELD

Embodiments described herein relate generally to integrated circuits and, more particularly, to integrated circuits with a voltage reference circuit.

### BACKGROUND

Integrated circuits often include voltage reference circuits for generating stable voltage signals. Certain mixed signal applications require low noise voltage reference circuits that typically include a direct current (DC) voltage source coupled to an RC filter (i.e., a filter having a series resistor and a shunt capacitor). It can be challenging to design a low noise voltage reference generator. The value of the series resistor and the value of the shunt capacitor tend to be fairly large to achieve the necessary low noise suppression.

The large resistor and capacitor values result in longer settling times at the output of the low noise voltage reference. To help shorten the long settling times, a unity gain buffer is used to charge the shunt capacitor. The unity gain buffer has an input coupled to the DC voltage source and has an output coupled to the shunt capacitor. In practice, the capacitor will initially be charged to a voltage level that is a function of an input voltage and an offset voltage associated with the unity gain buffer and a voltage drop across the series resistor in the presence of a loading current. The voltage at the capacitor will eventually settle to a final voltage level, the settling time still being dependent on an elevated time constant caused by the large RC values of the filter. It is within this context that the embodiments herein arise.

### SUMMARY

An electronic device may include an integrated circuit having voltage generation circuitry configured to generate a low noise reference voltage signal to one or more circuit components on the integrated circuit. The voltage generation circuitry may include a voltage source configured to generate a direct current (DC) voltage, a low-pass filter with one or more filtering stages, and an amplifier. For example, the low-pass filter can have at least two filter stages connected in series, at least three filter stages connected in series, or any number of low-pass filter stages cascaded in a chain or ladder. Each low-pass filter stage may include a series resistor and first and second shunt capacitors of equal capacitance. The amplifier may have an input selectively coupled to an output port of the voltage generation circuitry and an output selectively coupled to the first and second shunt capacitors in the low-pass filter.

The voltage generation circuitry may be operable in four phases: (1) an initial sensing phase, (2) a first charging phase, (3) a second charging phase, and (4) an amplifier offset cancelling phase. During the initial sensing phase, the output port can charge to a voltage level of the input voltage minus the IR voltage drop across the series resistors in a short time because the shunt capacitors are disconnected during this time, and the output port of the voltage generator circuitry may be coupled to the input of the amplifier while all of the shunt capacitors are disconnected. During the first charging phase, the amplifier may be used to charge the first capacitor in each low-pass filter stage. During the second charging phase, the amplifier can have its polarity swapped (chopped) and can be used to charge the second capacitor in each low-pass filter stage. During the amplifier offset cancelling phase, the first and second capacitors in each filter stage are shorted together to cancel out the offset voltage associated with the amplifier. Configured and operated in this way, the amplifier offset voltage can be eliminated while allowing the output port to instantaneously settle to the desired output voltage level.

An aspect of the disclosure provides voltage generation circuitry that includes a voltage source having an output, an amplifier having an input coupled to an output port of the voltage generation circuitry and having an output, and a filter circuit. The filter circuit can include a resistor having a first terminal coupled to the output of the voltage source and having a second terminal coupled to the output port of the voltage generation circuitry, a first capacitor having a first terminal coupled to the output of the amplifier and having a second terminal coupled to a ground power supply line, and a second capacitor having a first terminal coupled to the output of the amplifier and having a second terminal coupled to the ground power supply line. The first terminal of the first capacitor can also be coupled to the second terminal of the resistor, and the first terminal of the second capacitor can also coupled to the second terminal of the resistor.

The voltage generation circuitry can include an enabling switch coupled between the output port of the voltage generation circuitry and the input of the amplifier. The voltage generation circuitry can further include a first switch coupled between the first terminal of the first capacitor and the output of the amplifier, a second switch coupled between the first terminal of the second capacitor and the output of the amplifier, a third switch coupled between the first terminal of the first capacitor and the second terminal of the resistor, and a fourth switch coupled between the first terminal of the second capacitor and the second terminal of the resistor. The voltage generation circuitry can further include a control circuit configured to output a first control signal for controlling the first switch, a second control signal for controlling the second switch, and a third control signal for controlling the third and fourth switches. The amplifier can be a unity gain buffer and can include an input swapping circuit and an output swapping circuit.

An aspect of the disclosure provides a method of operating voltage generation circuitry having an output port and having a low-pass filter with first and second capacitors. The method can include: sensing an output voltage from the output port of the voltage generation circuitry at an input of an amplifier while the first and second capacitors are decoupled from the output port during a first phase; using the amplifier to charge the first capacitor in the low-pass filter during a second phase; using the amplifier having its polarity swapped (chopped) to charge the second capacitor in the low-pass filter during a third phase; and canceling an offset associated with the amplifier by coupling the first capacitor to the second capacitor during a fourth phase.

The method can include operating the amplifier in a first polarity during the second phase and operating the amplifier in a second polarity opposite to the first polarity during the third phase. The method can include: asserting a first control signal during the first phase to activate a first switch coupled between the output port of the voltage generation circuitry and the input of the amplifier; asserting a second control signal during the second phase to activate a second switch coupled between the first capacitor and the output of the amplifier; asserting a third control signal during the third phase to activate a third switch coupled between the second capacitor and the output of the amplifier; and asserting a fourth control signal during the fourth phase to activate a plurality of switches coupled between the first and second capacitors.

An aspect of the disclosure provides circuitry that includes: a first filter stage having a resistor, a first capacitor, and a second capacitor; a second filter stage having a resistor, a first capacitor, and a second capacitor, the second filter stage being coupled in series with the first filter stage; and an amplifier having an input selectively coupled to an output port of the circuitry and having an output that is selectively coupled to the first capacitors in the first and second filter stages during a first charging phase and that is selectively coupled to the second capacitors in the first and second filter stages during a second charging phase. The circuitry can have more than two cascaded filter stages, if desired. The first capacitor in the first filter stage can have a first capacitance value, and the second capacitor in the first filter stage can have the first capacitance value. The first capacitor in the second filter stage can have a second capacitance value, and the second capacitor in the second filter stage can have the second capacitance value. The amplifier can have a first signal polarity during the first charging phase and can have a second signal polarity opposite to the first signal polarity during the second charging phase.

Further features of the invention, its nature and various advantages will be more apparent from the accompanying drawings and following detailed description.

### BRIEF DESCRIPTION OF THE DRAWINGS

FIG. 1 is a diagram of an illustrative integrated circuit having low noise voltage generator circuitry in accordance with some embodiments.

FIG. 2 is a block diagram of illustrative voltage generator circuitry in accordance with some embodiments.

FIG. 3 is a circuit diagram showing one illustrative implementation of voltage generator circuitry in accordance with some embodiments.

FIG. 4 is a timing diagram showing illustrative waveforms involved in the operation of voltage generator circuitry of the type shown in FIG. 3 in accordance with some embodiments.

FIG. 5 is a diagram illustrating a snapshot of the voltage generator circuitry during an initial sensing phase in accordance with some embodiments.

FIG. 6 is a diagram illustrating a snapshot of the voltage generator circuitry during a first capacitor charging phase in accordance with some embodiments.

FIG. 7 is a diagram illustrating a snapshot of the voltage generator circuitry during a second capacitor charging phase in accordance with some embodiments.

FIG. 8 is a diagram illustrating a snapshot of the voltage generator circuitry during an offset canceling phase in accordance with some embodiments.

FIG. 9 is a flow chart of illustrative steps involved in operating the voltage generator circuitry of FIG. 3 in accordance with some embodiments.

FIG. 10 is a circuit diagram of an illustrative chopper amplifier in accordance with some embodiments.

### DETAILED DESCRIPTION

This relates to an integrated circuit having voltage generator circuitry. Such integrated circuit can be included within any type of electronic device or system, including but not limited to a cellular telephone, a tablet computer, a wristwatch, a laptop computer, a desktop computer, a monitor, a display with one or more displays, a media player, a digital content streaming device, a charger, an earbud, a headphone, a speaker, a stylus, a keyboard, an accessory, a wearable device, a head-mounted device, an automobile, or other electronic systems. The voltage generator circuitry can be a low noise voltage reference generator configured to generate a stable voltage signal for a wide range of electronic applications.

The voltage generator circuitry can include a voltage source, one or more low-pass filter stages, a chopper amplifier, multiple switches, and associated control logic for operating the voltage generator circuitry in multiple different phases. The chopper amplifier may have an input coupled to an output port of the voltage generator circuitry, an output selectively coupled to different portions of the low-pass filter stages, and a negative feedback connection. Each of the low-pass filter stages may have first and second capacitors with the same capacitance value.

The voltage generator circuitry may be operated in at least four different phases. In a first phase (sometimes referred to as a sensing phase), the output voltage is precharged quickly in the absence of the capacitors, and the amplifier is enabled and used to sense the voltage at the output port. In a second phase (sometimes referred to as a first charging phase), the amplifier charges the first capacitor in each of the filter stages. In a third phase (sometimes referred to as a second charging phase), the amplifier is chopped and is used to charge the second capacitor in each of the filter stages. In a fourth phase (sometimes referred to as an offset cancelling phase), the first and second capacitors are shorted together while the output port settles instantaneously to the desired final voltage level. Configured and operated in this way, any offset voltage of the chopper amplifier can be cancelled while minimizing the settling time at the output port of the voltage generator circuitry.

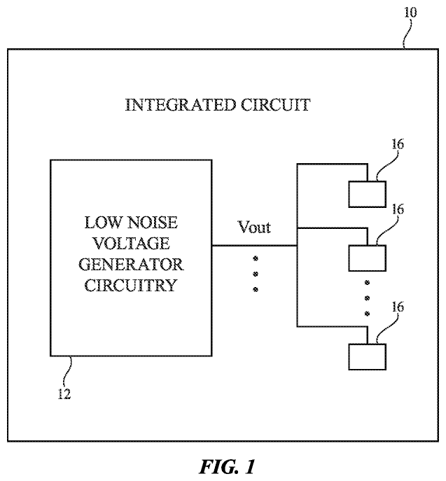

FIG. 1 is a diagram of an illustrative integrated circuit device such as integrated circuit 10 having voltage generator circuitry 12. Integrated circuit 10 can represent one or more processors such as a microprocessor, a microcontroller, a digital signal processor, a host processor, a baseband processor, an application processor, a central processing unit (CPU), a graphics processing unit (GPU), a power management integrated circuit (PMIC), a field-programmable gate array or programmable logic device, a sound (audio) chip, a wireless communications processor such as a radio-frequency transceiver chip, a combination of these circuits, or other types of integrated circuits.

Voltage generator circuitry 12 may be used to generate a low noise (stable) voltage signal Vout at its output port and is therefore sometimes referred to as a low noise voltage reference circuit. As shown in FIG. 1, output voltage Vout can be provided to one or more circuit components on device 10 such as components 16. Components 16 can be digital circuit components, analog circuit components, mixed-signal circuit components, the same type of circuit components, different types of circuit components, active circuit components, passive circuit components, and any electronic component(s) that might make use of a low noise voltage signal Vout.

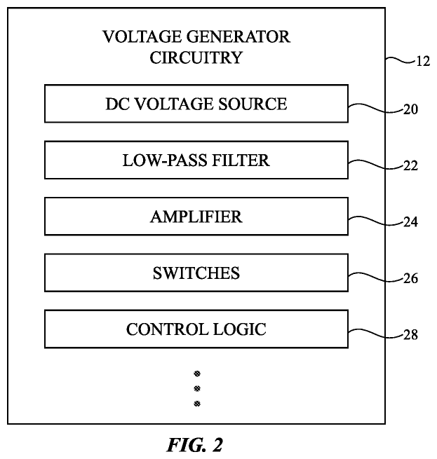

FIG. 2 is a block diagram of illustrative voltage generator circuitry 12. As shown in FIG. 2, voltage generator circuitry 12 may include a direct current (DC) voltage source such as DC voltage source 20, a filter circuit such as low-pass filter 22, an amplifying circuit such as amplifier 24, multiple switches 26, and associated controller logic such as control logic 28. The DC voltage source 20 may, for example, be a digital-to-analog converter (DAC) or other voltage source for generating a DC voltage. The low-pass filter 22 may represent one or more RC filter stages, each of which includes resistive and capacitive components. An “RC” filter stage may be defined as a low-pass filter stage having a series resistive component and shunt capacitive components. If desired, each RC filter stage can also be referred to as an RC filter, a low-pass filter, a filter circuit, or a filter.

Amplifier 24 may represent a chopper amplifier having an input coupled to an output port of voltage generator circuitry 12 and having an output selectively coupled to the capacitive components within the RC filter stages. A “chopper” amplifier is defined as an amplifier having at least swappable input terminals. The chopper amplifier also has an output terminal that can be rearranged. The switches 26 may be used to selectively couple the capacitive components within the RC filter stages to the output terminal of the chopper amplifier or to the series resistor. The control logic 28 may control the switches 26 during operation of voltage generator circuitry 12.

Voltage generator circuitry 12 may include additional components (not shown). Voltage generator circuitry 12 configured in this way may sometimes be referred to as a low noise voltage generator or a low noise voltage reference circuit.

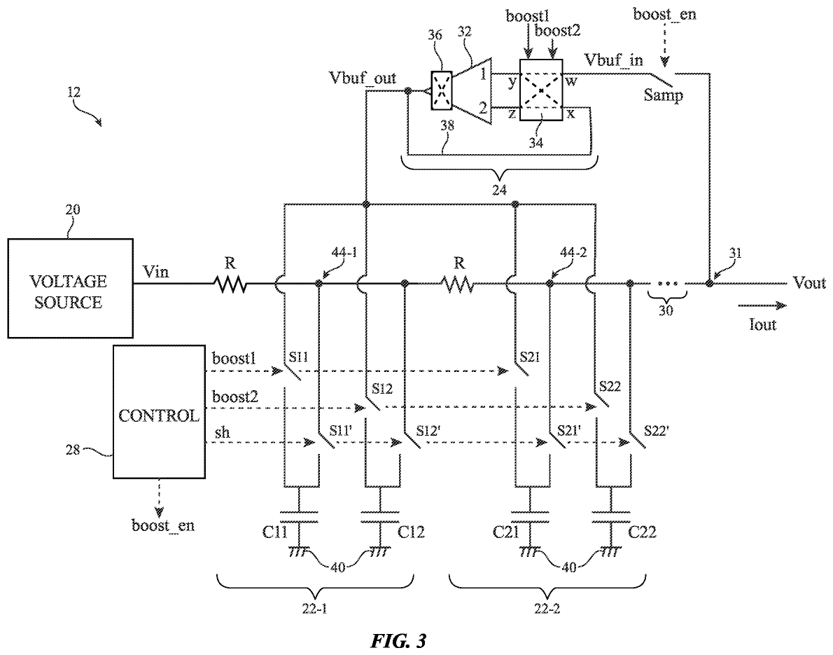

FIG. 3 is a circuit diagram showing one illustrative implementation of voltage generator circuitry 12. As shown in FIG. 3, voltage source 20 may generate a DC voltage Vin at its output, which is fed to the RC filter stages. Circuitry 12 includes a first RC filter stage 22-1 and a second RC filter stage 22-2. The use of two series RC filter stages is merely illustrative. In general, voltage generator circuitry 12 may include any number of RC filter stages (e.g., circuitry 12 can include one or more low-pass filters connected in a chain, three or more low-pass filters connected in a chain, four or more low-pass filters connected in a chain, five to ten low-pass filters connected in a chain, or more than ten low-pass filters).

First filter or filter stage 22-1 may include a first resistor R having a first terminal configured to receive DC voltage from the output of voltage source 20 and having a second terminal coupled to filter node 44-1. The first resistor R connected in this way is sometimes referred to as a series resistance. Filter 22-1 may further include a first capacitor C11 and a second capacitor C12 having the same capacitance values (e.g., the capacitance of C11 is identical to the capacitance of C12). Capacitor C11 has a first terminal that is selectively coupled to the output of amplifier 24 via a switch S11 and that is selectively coupled to filter node 44-1 via a switch S11′ and has a second terminal that is coupled to a ground power supply line 40. Ground power supply voltage line 40 is sometimes referred to as a ground line or ground. Capacitor C12 has a first terminal that is selectively coupled to the output of amplifier 24 via a switch S12 and that is selectively coupled to filter node 44-1 via a switch S12′ and has a second terminal that is coupled to ground line 40. Capacitors C11 and C12 connected in this way are sometimes referred to as shunt capacitances. Capacitors C11 and C12 having equal capacitance is sometimes referred to as having split capacitance.

Second filter or filter stage 22-2 may include a second resistor R having a first terminal couple to first filter node 44-1 and having a second terminal coupled to second filter node 44-2. The second resistor R connected in this way is also sometimes referred to as a series resistance. The series resistance of the various filter stages within circuitry 12 may be the same or may be different. Filter 22-2 may further include a first capacitor C21 and a second capacitor C22 having the same capacitance values (e.g., the capacitance of C21 is identical to the capacitance of C22). The capacitance value of C21 and C22, however, does not have be to the same as the capacitance value of C11 and C12 (e.g., the capacitance value of C11 and C12 can be the same or can be different from the capacitance value of C21 and C22). Capacitor C21 has a first terminal that is selectively coupled to the output of amplifier 24 via a switch S21 and that is selectively coupled to filter node 44-2 via a switch S21′ and has a second terminal that is coupled to ground power supply line 40. Capacitor C22 has a first terminal that is selectively coupled to the output of amplifier 24 via a switch S22 and that is selectively coupled to filter node 44-2 via a switch S22′ and has a second terminal that is coupled to ground 40. Capacitors C21 and C22 connected in this way are also sometimes referred to as shunt capacitances.

If desired, additional filters (filter stages) can be interposed between second filter node 44-2 and output port 31 of voltage generation circuitry 12 (as shown by ellipses 30). In an example where circuitry 12 includes only two RC filter stages, node 44-2 will be directly coupled (shorted) to output port 31. Low noise voltage generator output voltage Vout may be provided at output port 31.

Switches S11, S11′, S12, S12′, S21, S21′, S22, and S22′ connected to the filter capacitors may be referred to as capacitor switches. The capacitor switches may be controlled using control logic 28. Control logic 28 may be configured to output control signals boost1, boost2, sh, and boost_en. Control signal boost1 may be used to control switches S11 and S21 (e.g., signal boost1 may be asserted to turn on or activate switches S11 and S21 and deasserted to turn off or deactivate switches S11 and S21). Control signal boost2 may be used to control switches S12 and S21 (e.g., signal boost2 may be asserted to turn on or activate switches S12 and S22 and deasserted to turn off or deactivate switches S12 and S22). Control signal sh may be used to control switches S11′, S12′, S21′, and S22′ (e.g., signal sh may be asserted to turn on or activate switches S11′, S12′, S21′, and S22′ and deasserted to turn off or deactivate switches S11′, S12′, S21′, and S22′).

Amplifier 24 has an input coupled to voltage generator output port 31 via a switch Samp and an output that is selectively coupled to capacitor C11 using switch S11, to capacitor C12 using switch S12, to capacitor C21 using switch S21, and to capacitor C22 using switch S22. Switch Samp may be controlled using control signal boost_en output from control logic 28 (e.g., signal boost_en may be asserted to turn on or activate switch Samp and deasserted to turn off or deactivate switch Samp). Amplifier 24 may include a differential amplifier 32 (e.g., an amplifier having at least differential inputs) having a first input, a second input, and an output on which amplifier output signal Vbuf_out is generated.

Amplifier 24 has an input port configured to receive input voltage Vbuf_in. When switch Samp is turned off, the amplifier input port is decoupled from the output port 31 of voltage generator circuitry 12, and amplifier 24 can turn off. When switch Samp is turned on, the amplifier input port is coupled to output port 31 so that voltage Vbuf_in is driven equal to Vout. Amplifier 24 may include an input swapping circuit 34 for selectively (re)routing voltage Vbuf_in to either the first or second input of amplifier 32. Input swapping circuit 34 has a first (w) input terminal configured to receive voltage Vbuf_in, a second (x) input terminal coupled to the output of amplifier 32 via feedback path 38, a first (y) output terminal coupled to the first (1) input of amplifier 32, and a second (z) output terminal coupled to the second (2) input of amplifier 32. Input swapping circuit 34 (sometimes referred to as an input rerouting circuit) may be controlled using signals boost1 and boost2 output from control logic 28. When signal boost1 is asserted, input terminals w and x are connected to output terminals y and z, respectively, so that Vbuf_in is routed to the first amplifier input and the negative feedback path 38 is coupled to the second amplifier input. When signal boost2 is asserted, input terminals w and x are connected to output terminals z and y, respectively, so that Vbuf_in is routed to the second (2) amplifier input and the negative feedback path 38 is coupled to the first (1) amplifier input.

Amplifier 24 may also include an output swapping circuit 36 for selectively (re)routing its output to different internal nodes within amplifier 32. Output swapping circuit 36 (sometimes referred to as an output rerouting circuit) may also be using signals boost1 and boost2 output from control logic 28. When signal boost1 is asserted, the output of amplifier 24 is coupled to a first internal node within amplifier 32. When signal boost2 is asserted, the output of amplifier 24 is coupled to a second internal node within amplifier 32. Thus, when signal boost1 is asserted and signal boost2 is deasserted, voltage Vbuf_in is provided at a first signal polarity to the inputs of amplifier 32 while amplifier output voltage Vbuf_out is fed back to maintain a negative feedback loop. When signal boost2 is asserted and signal boost1 is deasserted, voltage Vbuf_in is provided at a second signal polarity (opposite to the first signal polarity) to the inputs of amplifier 32 while amplifier output voltage Vbuf_out is fed back to maintain a negative feedback loop. Amplifier 24 configured and operated in this way to swap (alternate) the signal polarities is sometimes referred to as a chopper amplifier. Amplifier 24 having negative feedback connection 38 and having a gain of one is sometimes referred to as a unity gain buffer.

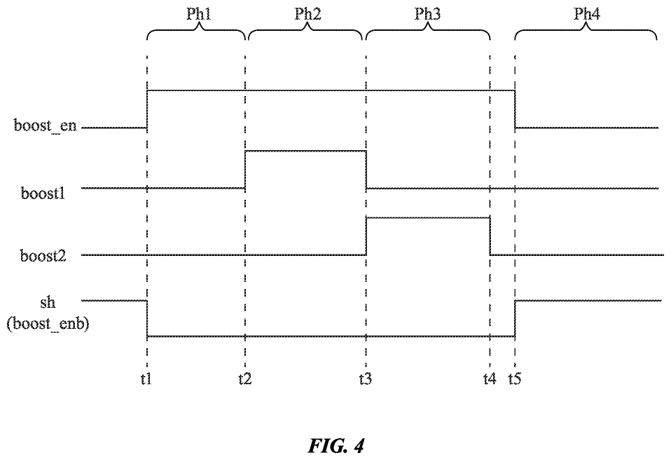

FIG. 4 is a timing diagram showing illustrative waveforms involved in the operation of voltage generator circuitry 12 of the type shown in FIG. 3. As shown in FIG. 4, voltage generator circuitry 12 may be operable in at least four different phases. Prior to time t1, signals boost_en, boost1, and boost2 are deasserted, and only signal sh is asserted.

During a first phase Ph1 from time t1 to t2, signal boost_en may be asserted (e.g., driven high). Asserting signal boost_en may turn on switch Samp, which couples output port 31 to the input port of amplifier 24. During this time, all of the filter capacitors are disconnected from nodes 44-1 and 44-2, and amplifier 24 may sense the voltage Vout at output port 31. In practice, there may be some load current that flows out of output port 31 (indicated by current Iout). Load current Iout (sometimes referred to as output current) may be due to gate leakage of a subsequent complementary metal-oxide-semiconductor (CMOS) device or base current of a bipolar junction transistor (BJT), as examples. Thus, voltage Vout at output port 31 may be expressed as follows:

Vout=Vin−n*Iout*R (1)

where n is equal to the number of low-pass filter stages and where R represents the resistance of the series resistor in each filter stage. In the example where voltage generation circuitry 12 includes two filter stages, voltage Vout will be quickly charged to the DC source voltage Vin minus two times the product of Iout and R (i.e., Vout=Vin−2*Iout*R) since all the filter capacitors are disconnected from the series current path.

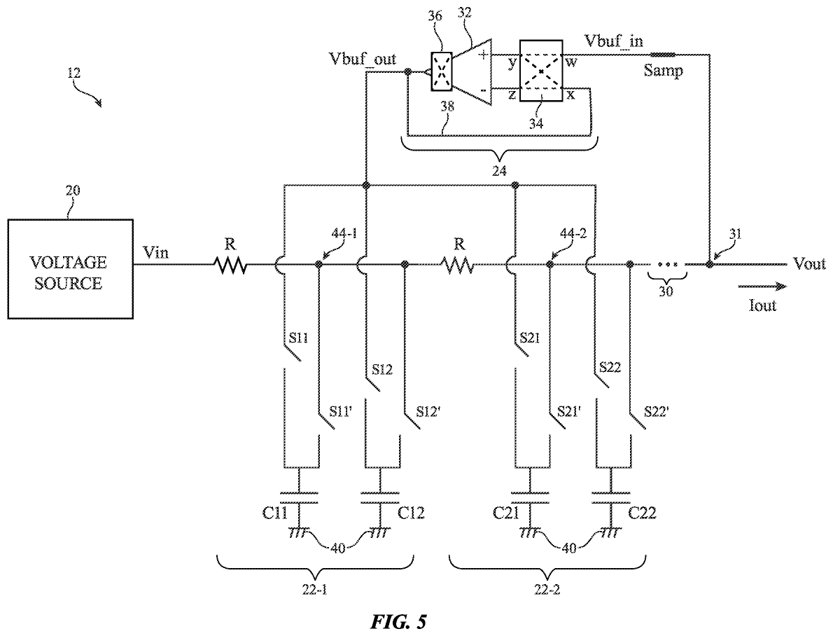

FIG. 5 is a diagram illustrating a snapshot of the voltage generator circuitry during the first phase Ph1. As shown in FIG. 5, only switch Samp is closed (turned on) so the amplifier input voltage Vbuf_in effectively becomes generator output voltage Vout, which is equal to the expression shown in equation 1. Thus, at the end of the first phase Ph1 (at time t2), amplifier input voltage Vbuf_in should be equal to (Vin-2*Iout*R) that is sensed at output port 31. The first phase Ph1 is therefore sometimes referred to as the sensing phase.

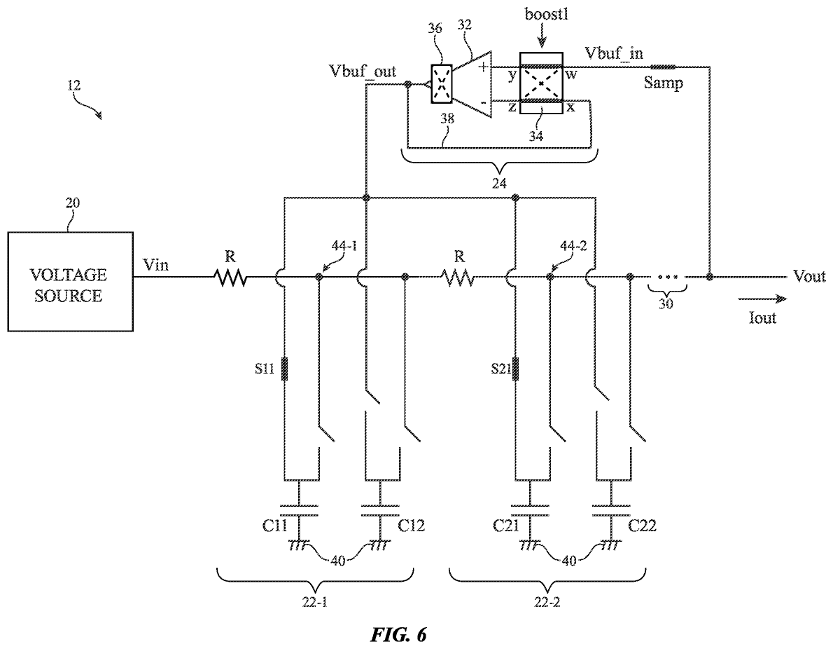

During a second phase Ph2 from time t2 to t3, signal boost1 may be asserted (e.g., pulse high). FIG. 6 is a diagram illustrating a snapshot of voltage generator circuitry 12 during the second phase Ph2. As shown in FIG. 6, switch Samp remains activated while the asserted boost1 signal places swapping circuits 34 and 36 in a first state so that amplifier 24 has a first polarity. In the first polarity, amplifier 24 may drive Vbuf_out to the following voltage level:

Vbuf_out=Vin−n*Iout*R+Vos (2)

where Vos represents an offset voltage associated with amplifier 32. Pulsing high signal boost1 will turn on switches S11 and S21, which will charge capacitors C11 and C21, respectively, to the value shown in equation 2 above. The second phase Ph2 is therefore sometimes referred to as a first charging phase or a first amplifier boosting phase.

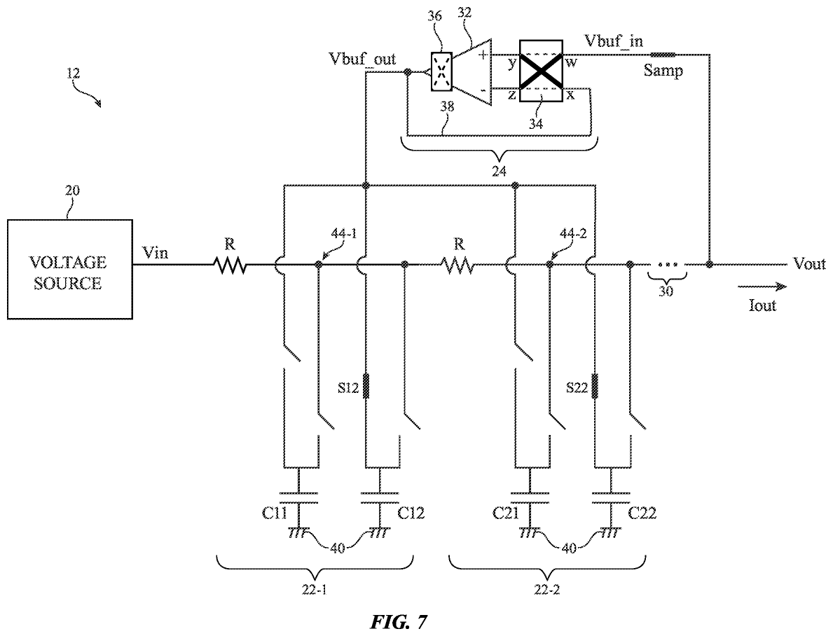

During a third phase Ph3 from time t3 to t4, signal boost2 may be asserted (e.g., pulse high). FIG. 7 is a diagram illustrating a snapshot of voltage generator circuitry 12 during the third phase Ph3. As shown in FIG. 7, switch Samp remains activated while the asserted boost2 signal places swapping circuits 34 and 36 in a second state so that amplifier 24 has a second polarity opposite of the first polarity. Reversing the polarity of amplifier 24 is sometimes referred to as “chopping” amplifier 24. In the second (inverted) polarity, amplifier 24 may drive Vbuf_out to the following voltage level:

Vbuf_out=Vin−n*Iout*R−Vos (3)

where Vos again represents an offset voltage associated with amplifier 32 but is now a negative term due to the polarity swap. Pulsing high signal boost2 will turn on switches S12 and S22, which will charge capacitors C12 and C22, respectively, to the value shown in equation 3 above. The third phase Ph3 is therefore sometimes referred to as a second charging phase or a second amplifier boosting phase.

During a fourth phase Ph4 starting at time t5, signal boost_en is deasserted (e.g., driven low) and signal sh may be asserted (e.g., driven high). Deasserting signal boost_en deactivates (turns off) switch Samp, which decouples amplifier 24 from the voltage generator output port 31. Asserting signal sh will activate switches S11′ and S12′ to short both capacitors C11 and C12 in filter 22-1 to node 44-1 and will also activate switches S21′ and S22′ to short both capacitors C21 and C22 in filter 22-2 to node 44-2. Signal sh is therefore sometimes referring to as the capacitor shorting signal. In the example of FIG. 4, signal sh is simply implemented as an inverted version of signal boost_en. This is merely illustrative. In general, signal sh can be decoupled from signal boost_en as long as signal sh is asserted after signal boost_en is deasserted to start phase Ph4.

Since capacitors C11 and C21 store the +Vos voltage while capacitors C12 and C22 store the −Vos voltage, shorting capacitors C11 and C12 together and shorting capacitors C21 and C22 together will effectively cancel out the amplifier offset voltage via charge averaging. The fourth phase Ph4 is therefore sometimes referred to as an offset cancelling phase. Since the filter capacitors are already charged to their respective voltage levels during the charging phases Ph2 and Ph3, the output voltage Vout will arrive at the desired steady-state voltage of (Vin−2*Iout*R) instantaneously (while simultaneously canceling out offset voltage Vos) without the effects of any large time constant. To shorten the duration of the charging periods Ph2 and Ph3, the power of amplifier 24 can be increased to improve the bandwidth of the feedback loop.

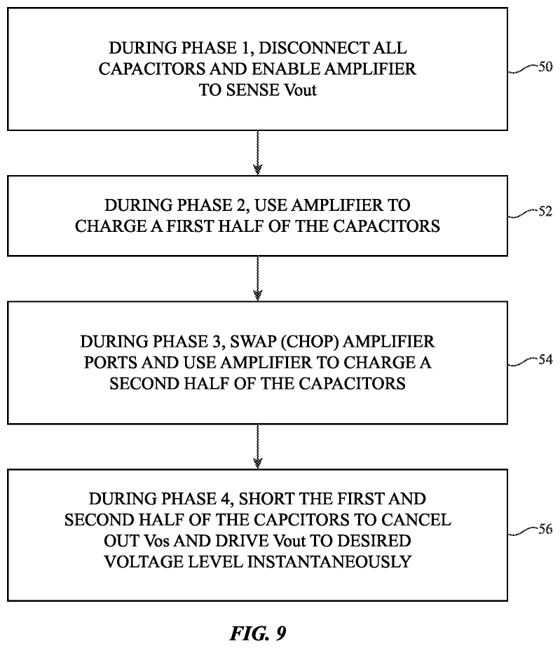

FIG. 9 is a flow chart of illustrative steps involved in operating the voltage generator circuitry 12. In the operations of block 50, all of the filter capacitors may be disconnected, and amplifier 24 may be enabled to sense the generator output voltage Vout. This may correspond to the sensing phase Ph1 of FIG. 4 and the snapshot of FIG. 5. During this time, amplifier 24 may sense a voltage level equal to (Vin−2*Iout*R) at its input port.

In the operations of block 52, amplifier 24 may be used to charge a first half of the filter capacitors. This may correspond to the first charging phase Ph2 of FIG. 4 and the snapshot of FIG. 6. During this time, amplifier 24 may charge the first half of the filter capacitors (e.g., capacitor C11 in the first filter stage, capacitor C21 in the second filter stage, and the first capacitor in any additional filter stages) to a voltage level equal to (Vin−2*Iout*R+Vos).

In the operations of block 54, amplifier 24 may be chopped and may be used to charge a second half of the filter capacitors. This may correspond to the second charging phase Ph3 of FIG. 4 and the snapshot of FIG. 7. During this time, chopped amplifier 24 may charge the second half of the filter capacitors (e.g., capacitor C12 in the first filter stage, capacitor C22 in the second filter stage, and the second capacitor in any additional filter stages) to a voltage level equal to (Vin−2*Iout*R−Vos).

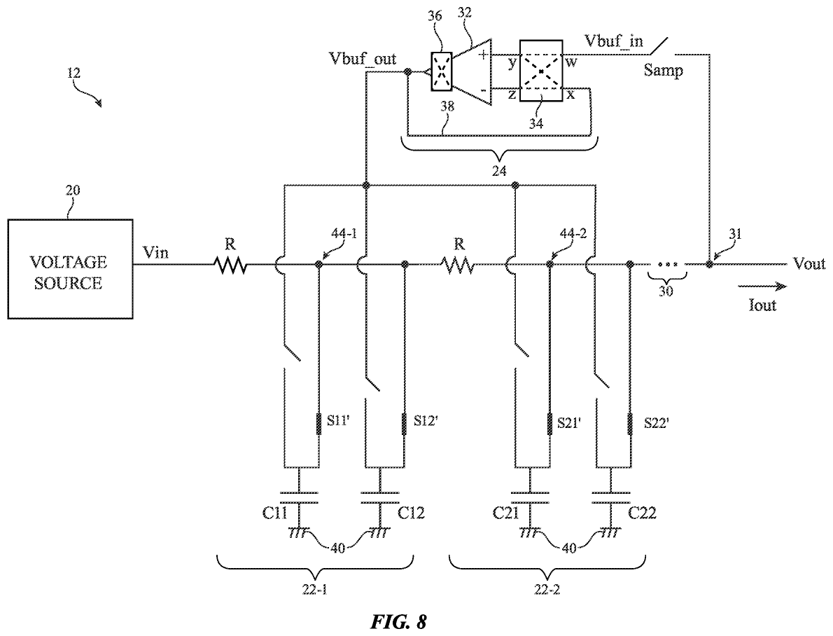

In the operations of block 56, the first and second half of filter capacitors in each filter stage may be shorted together so that charge average can cancel out the Vos component. This may correspond to the offset canceling phase Ph4 of FIG. 4 and the snapshot of FIG. 8. During this time, the first capacitors holding +Vos component may be shorted with the second capacitors holding the −Vos component, and the offset voltage cancellation can occur almost instantaneously. Since all of the filter capacitors have already been charged up during the operations of blocks 52 and 54, the output voltage Vout can arrive at the desired steady-state voltage of (Vin−2*Iout*R) instantaneously without incurring long RC settling times.

The operations of FIG. 9 are merely illustrative. At least some of the described operations may be modified or omitted; some of the described operations may be performed in parallel; additional processes may be added or inserted between the described operations; the order of certain operations may be reversed or altered; and/or the timing of the described operations may be adjusted so that they occur at slightly different times. For example, the operations of block 54 can be performed before the operations of block 52, so long as the polarity of amplifier 24 is swapped (chopped) when transitioning from block 54 to block 52. If desired, the operations of block 50 might be performed at the same time as the operations of block 52 (e.g., the operations of blocks 50 and 52 can be performed simultaneously).

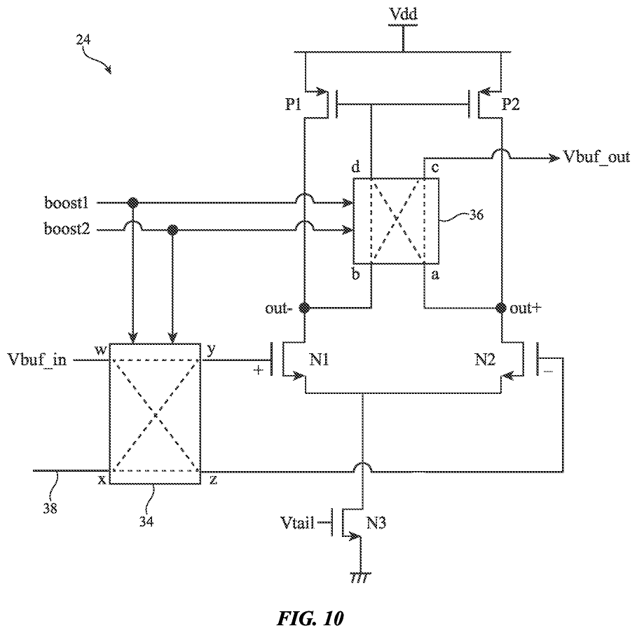

FIG. 10 is a circuit diagram showing one illustrative implementation of a chopper amplifier 24. As shown in FIG. 10, amplifier 24 may include n-type transistors such as n-type metal-oxide-semiconductor (NMOS) transistors N1, N2, and N3, p-type transistors such as p-type metal-oxide-semiconductor (PMOS) transistors P1 and P2, input swapping (chopping) circuit 34 and output swapping (chopping) circuit 36. Transistors N1 and N2 may serve as amplifier input transistors.

Input chopping circuit 34 may have a first input port w configured to receive Vbuf_in from output port 31, a second input port w coupled to feedback connection 38, a first output port y coupled to the gate terminal of input transistor N1, and a second output port z coupled to the gate terminal of input transistor N2. Input chopping circuit 34 may be adjusted using control signals boost1 and boost2. When signal boost1 is asserted, circuit 34 may be configured in a first polarity to connect input ports w and x to output ports y and z, respectively. When signal boost2 is asserted, circuit 34 may be configured in a second (opposite) polarity to connect input ports w and x to output ports z and y, respectively.

Transistor N3 may have a drain terminal coupled to the source terminals of input transistors N1 and N2, a gate terminal configured to receive bias voltage Vtail, and a source terminal coupled to the ground line. Transistor N3 arranged in this way is sometimes referred to as the tail transistor. P-type transistor P1 may have a source terminal coupled to the positive power supply line (e.g., a positive power supply terminal on which positive power supply voltage Vdd is provided), a gate terminal, and a drain terminal coupled to the drain terminal of input transistor N1. P-type transistor P2 may have a source terminal coupled to the positive power supply line, a gate terminal shorted to the gate terminal of transistor P1, and a drain terminal coupled to the drain terminal of input transistor N2.

Output chopping circuit 36 may have a first input port a coupled to the drain terminal of input transistor N2, a second input port b coupled to the drain terminal of input transistor N1, a first output port c on which voltage Vbuf_out is generated, and a second output port d coupled to the gate terminals of transistors P1 and P2. Output chopping circuit 36 may also be adjusted using control signals boost1 and boost2. When signal boost1 is asserted, circuit 36 may be configured in a first polarity to connect input ports a and b to output ports c and d, respectively. When signal boost2 is asserted, circuit 36 may be configured in a second (opposite) polarity to connect input ports a and b to output ports d and c, respectively.

Chopper amplifier 24 of the type shown in FIG. 10 is merely illustrative. If desired, amplifier 24 can be implemented as a cascode amplifier, a folded cascode amplifier, a telescopic amplifier, a multi-stage amplifier, a combination of these amplifiers, or may employ other differential amplifier architectures.

The foregoing is merely illustrative and various modifications can be made to the described embodiments. The foregoing embodiments may be implemented individually or in any combination.

What is claimed is:

1. Voltage generation circuitry comprising:
a voltage source;
an amplifier having an input coupled to an output port of the voltage generation circuitry; and
a filter circuit that includes
a resistor having a first terminal coupled to an output of the voltage source and having a second terminal coupled to the output port of the voltage generation circuitry,
a first capacitor having a first terminal selectively coupled to an output of the amplifier and having a second terminal coupled to a ground power supply line, and
a second capacitor having a first terminal selectively coupled to the output of the amplifier and having a second terminal coupled to the ground power supply line.

2. The voltage generation circuitry of claim 1, wherein the first terminal of the first capacitor is selectively coupled to the second terminal of the resistor and wherein the first terminal of the second capacitor is selectively coupled to the second terminal of the resistor.

3. The voltage generation circuitry of claim 2, further comprising:
a switch coupled between the output port of the voltage generation circuitry and the input of the amplifier.

4. The voltage generation circuitry of claim 2, further comprising:
a first switch coupled between the first terminal of the first capacitor and the output of the amplifier; and
a second switch coupled between the first terminal of the second capacitor and the output of the amplifier.

5. The voltage generation circuitry of claim 4, further comprising:
a third switch coupled between the first terminal of the first capacitor and the second terminal of the resistor; and
a fourth switch coupled between the first terminal of the second capacitor and the second terminal of the resistor.

6. The voltage generation circuitry of claim 5, further comprising:
a control circuit configured to output a first control signal for controlling the first switch, a second control signal for controlling the second switch, and a third control signal for controlling the third and fourth switches.

7. The voltage generation circuitry of claim 6, further comprising:
a fifth switch coupled between the output port of the voltage generation circuitry and the input of the amplifier, the control circuit being configured to output a fourth control signal for controlling the fifth switch.

8. The voltage generation circuitry of claim 7, wherein the third control signal is an inverted version of the fourth control signal.

9. The voltage generation circuitry of claim 1, wherein the first capacitor and the second capacitor have the same capacitance value.

10. The voltage generation circuitry of claim 1, wherein the amplifier is connected in a unity gain configuration.

11. The voltage generation circuitry of claim 1, wherein the amplifier comprises an input swapping circuit.

12. The voltage generation circuitry of claim 11, wherein the amplifier further comprises an output swapping circuit.

13. The voltage generation circuitry of claim 1, wherein the filter circuit further comprises:
an additional resistor having a first terminal coupled to the second terminal of the resistor in the filter circuit and having a second terminal coupled to the output port of the voltage generation circuitry;
a third capacitor having a first terminal coupled to the output of the amplifier and to the output port of the voltage generation circuitry and having a second terminal coupled to the ground power supply line; and
a fourth capacitor having a first terminal coupled to the output of the amplifier and to the output port of the voltage generation circuitry and having a second terminal coupled to the ground power supply line.

14. The voltage generation circuitry of claim 1, wherein the voltage source is configured to generate a direct current (DC) voltage signal.

15. A method of operating voltage generation circuitry having an output port, an amplifier, and a low-pass filter with first and second capacitors, the method comprising:
during a first phase, sensing, at an input of the amplifier, an output voltage from the output port of the voltage generation circuitry;
during a second phase, using the amplifier to charge the first capacitor in the low-pass filter;
during a third phase, using the amplifier to charge the second capacitor in the low-pass filter; and
during a fourth phase, canceling an offset associated with the amplifier by coupling the first capacitor to the second capacitor.

16. The method of claim 15, further comprising:
operating the amplifier in a first polarity during the second phase; and
operating the amplifier in a second polarity opposite to the first polarity during the third phase.

17. The method of claim 15, further comprising:
asserting a first control signal during the first phase to activate a first switch coupled between the output port of the voltage generation circuitry and the input of the amplifier;
asserting a second control signal during the second phase to activate a second switch coupled between the first capacitor and an output of the amplifier;
asserting a third control signal during the third phase to activate a third switch coupled between the second capacitor and the output of the amplifier; and
asserting a fourth control signal during the fourth phase to activate a plurality of switches coupled between the first and second capacitors.

18. The method of claim 15, further comprising:
during the second phase, using the amplifier to charge a third capacitor in the low-pass filter;
during the third phase, using the amplifier to charge a fourth capacitor in the low-pass filter; and
during the fourth phase, canceling the offset associated with the amplifier by coupling together the third and fourth capacitors in the low-pass filter.

19. Circuitry comprising:
a first filter stage having a first resistor, a first capacitor, and a second capacitor;
a second filter stage having a second resistor, a third capacitor, and a fourth capacitor, the second filter stage being coupled in series with the first filter stage; and
an amplifier having an input selectively coupled to an output port of the circuitry and having an output that is selectively coupled to the first and third capacitors during a first charging phase and that is selectively coupled to the second and fourth capacitors during a second charging phase.

20. The circuitry of claim 19 wherein:
the first capacitor in the first filter stage has a first capacitance value, and the second capacitor in the first filter stage has the first capacitance value;
the third capacitor in the second filter stage has a second capacitance value, and the fourth capacitor in the second filter stage has the second capacitance value;
the amplifier has a first polarity during the first charging phase; and
the amplifier has a second polarity opposite to the first polarity during the second charging phase.
